(19) United States
(12) Patent Application Publication
(10) Pub. No.: US 2026/0334178 A1
(43) Pub. Date: Oct. 22, 2026

(54) SEMICONDUCTOR DEVICE AND METHOD OF MANUFACTURING THE SAME

(71) Applicant: NANYA TECHNOLOGY CORPORATION, New Taipei City (TW)

(72) Inventor: Jen-I LAI, New Taipei City (TW)

(21) Appl. No.: 19/722,991

(22) Filed: Jun. 29, 2026

Related U.S. Application Data
(62) Division of application No. 18/208,142, filed on Jun. 9, 2023, now Pat. No. 12,727,452.

(51) Int. Cl. H10W 10/00; H10P 30/40; H10P 50/28; H10P 95/00; H10W 10/17

(52) U.S. Cl. CPC H10W 10/014; H10P 30/40; H10P 50/283; H10P 95/06; H10W 10/17

(57) ABSTRACT

The present disclosure provides a semiconductor device. The semiconductor structure includes a silicon substrate and an oxide material. The silicon substrate has a plurality of trenches. The trenches define a plurality of island structures. The oxide material is filled in the trenches. Each of the island structures has a top surface, a side surface connected to the top surface, and a rounded edge connected between the top surface and the side surface. A radius of curvature of the rounded edge is equal or less than 2.3 nm.

### CROSS-REFERENCE TO RELATED APPLICATION

This application is a Divisional Application of U.S. application Ser. No. 18/208,142, filed on Jun. 9, 2023, which is herein incorporated by reference in its entirety.

### BACKGROUND

### Field of Invention

The present disclosure relates to a semiconductor device and a method of manufacturing the same.

### Description of Related Art

With the evolution of generations of semiconductor processes, there will be challenges of a semiconductor structure in a memory device. Regarding semiconductor devices, the process related to active area in dynamic-random access memory (DRAM) is pivotal, because it determines the performance and yield enhancement of the semiconductor devices.

However, conventional methods bring out rounding scheme of the active area. This may lead to less contact area where the active area in contact with contacts, thereby causing deterioration of electrical performance of the semiconductor devices. Based on previous experiments, although decreasing the time of wet cleaning the active area may mitigate the rounding issue of the active area, the shallow trench isolation (STI) loss issue remains unsolved.

### SUMMARY

In view of this, one purpose of present disclosure is to provide a semiconductor device and a method of manufacturing the same that can solve the aforementioned problems.

In order to achieve the above objective, according to an embodiment of the present disclosure, a semiconductor structure includes a silicon substrate and an oxide material. The silicon substrate has a plurality of trenches. The trenches define a plurality of island structures. The oxide material is filled in the trenches. Each of the island structures has a top surface, a side surface connected to the top surface, and a rounded edge connected between the top surface and the side surface. A radius of curvature of the rounded edge is equal or less than 2.3 nm.

In one or more embodiments of the present disclosure, a top surface of the oxide material and the top surface of the island structures are coplanar.

In one or more embodiments of the present disclosure, the oxide material does not overfill the trenches.

In one or more embodiments of the present disclosure, each of the island structures has a width in a range between 20 nm and 30 nm.

In one or more embodiments of the present disclosure, the oxide material contacts a plurality of the side surfaces and a plurality of the rounded edges of the island structures.

In one or more embodiments of the present disclosure, the oxide material covers a plurality of the side surfaces and a plurality of the rounded edges of the island structures.

In one or more embodiments of the present disclosure, the semiconductor device further includes a filling material on the oxide material.

In one or more embodiments of the present disclosure, the filling material and the oxide material completely fill the trenches.

In one or more embodiments of the present disclosure, the filling material does not overfill the trenches.

In one or more embodiments of the present disclosure, a top surface of the oxide material and a top surface of the filling material are coplanar.

In one or more embodiments of the present disclosure, a plurality of the top surfaces of the island structures, a top surface of the oxide material, and a top surface of the filling material are coplanar.

In one or more embodiments of the present disclosure, the filling material is filled in seams or voids of the oxide material.

In one or more embodiments of the present disclosure, the seams or the voids of the oxide material are recessed from a top surface of the oxide material.

In one or more embodiments of the present disclosure, the oxide material exposes a plurality of the top surfaces of the island structures.

In one or more embodiments of the present disclosure, the trenches are recessed from a top surface of the silicon substrate.

In summary, the semiconductor device and the method of manufacturing the same of the present disclosure provides island structures without rounding issues. In the semiconductor device and the method of manufacturing the same of the present disclosure, since the pad oxide layer is formed on the top of the semiconductor structure and covering the island structures, the loss of the oxide material can be reduced, thereby prevent rounding of the island structures. In the semiconductor device and the method of manufacturing the same of the present disclosure, since the pad oxide layer is formed on the top portion of the oxide material in situ, additional material is not required, thereby improving the electrical performance of the entire semiconductor device. To sum up, the method of manufacturing the semiconductor device of the present disclosure improves the overall electrical performance of the entire semiconductor device.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a flow chart of a method of manufacturing a semiconductor device in accordance with an embodiment of present disclosure;

FIG. 2 is a cross-sectional view of an intermediate stage of manufacturing a semiconductor device in accordance with an embodiment of present disclosure;

FIG. 3 is a cross-sectional view of an intermediate stage of manufacturing the semiconductor device in accordance with another embodiment of present disclosure;

FIG. 4 is a cross-sectional view of an intermediate stage of manufacturing the semiconductor device in accordance with an embodiment of present disclosure;

FIG. 5 is a cross-sectional view of an intermediate stage of manufacturing the semiconductor device in accordance with an embodiment of present disclosure;

FIG. 6 is a cross-sectional view of an intermediate stage of manufacturing the semiconductor device in accordance with an embodiment of present disclosure;

FIG. 7 is a cross-sectional view of an intermediate stage of manufacturing the semiconductor device in accordance with another embodiment of present disclosure; and

FIG. 8 is an enlarged cross-sectional view of FIG. 6 or FIG. 7 of an intermediate stage of manufacturing the semiconductor device in accordance with an embodiment of present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around,” “about,” “approximately,” or “substantially” shall generally mean within 20 percent, or within 10 percent, or within 5 percent of a given value or range. Numerical quantities given herein are approximate, meaning that the term “around,” “about,” “approximately,” or “substantially” can be inferred if not expressly stated.

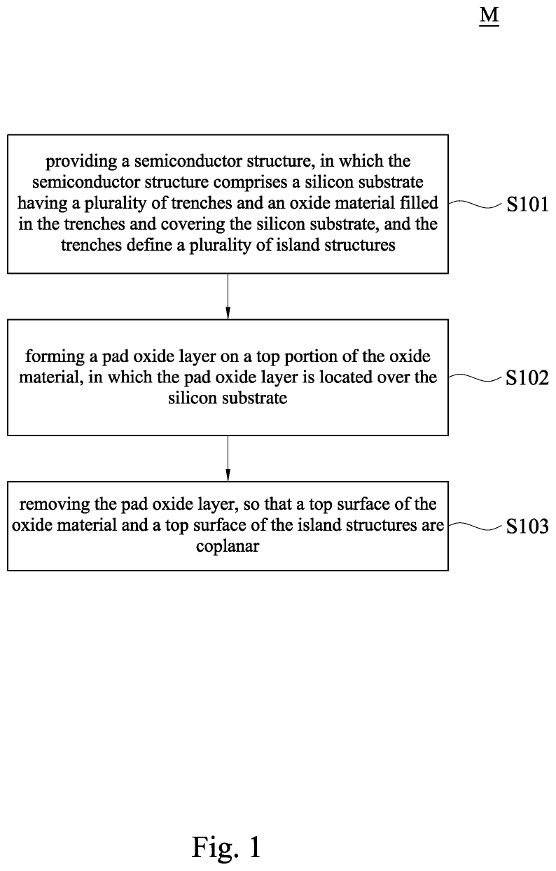

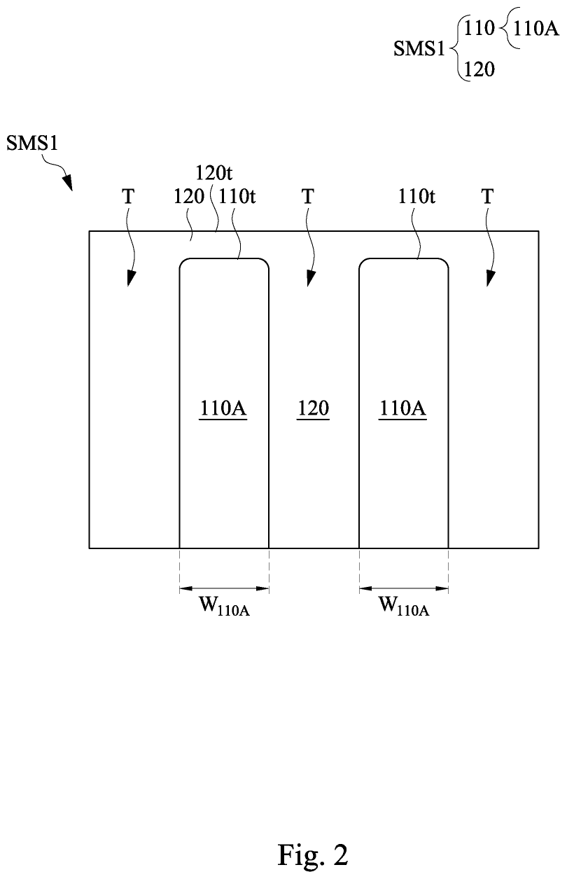

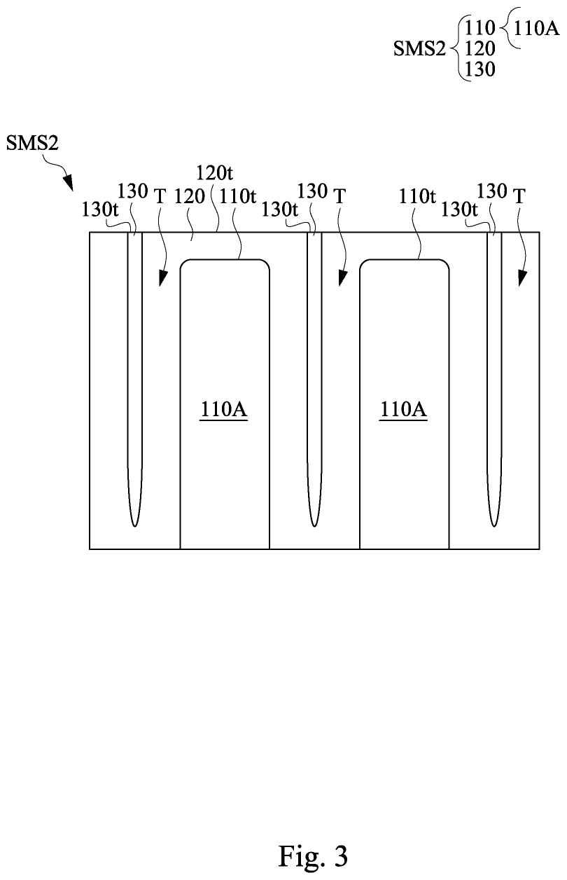

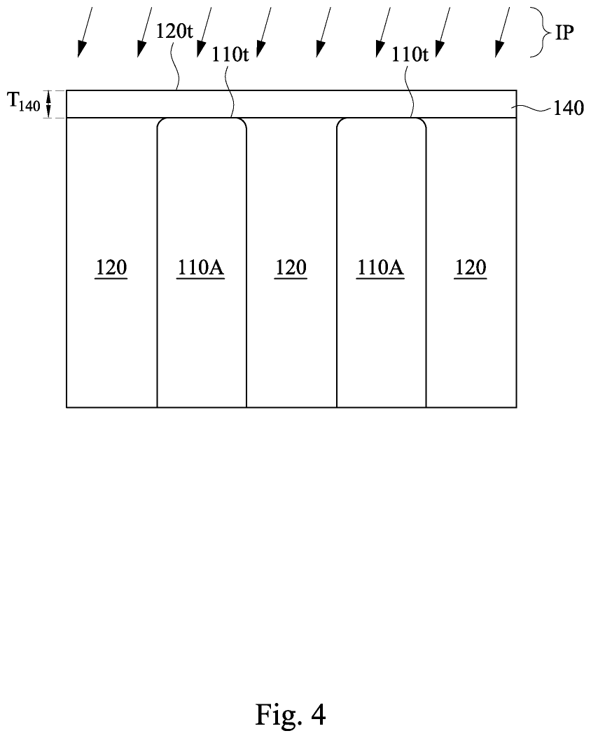

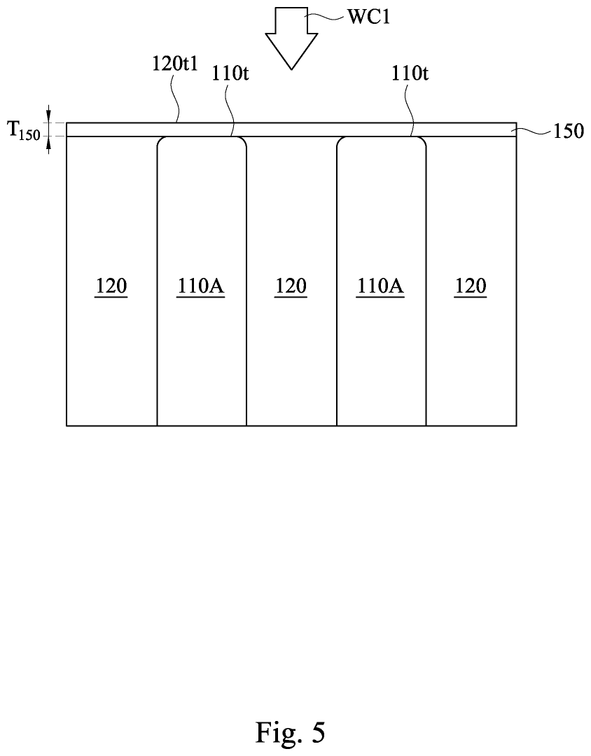

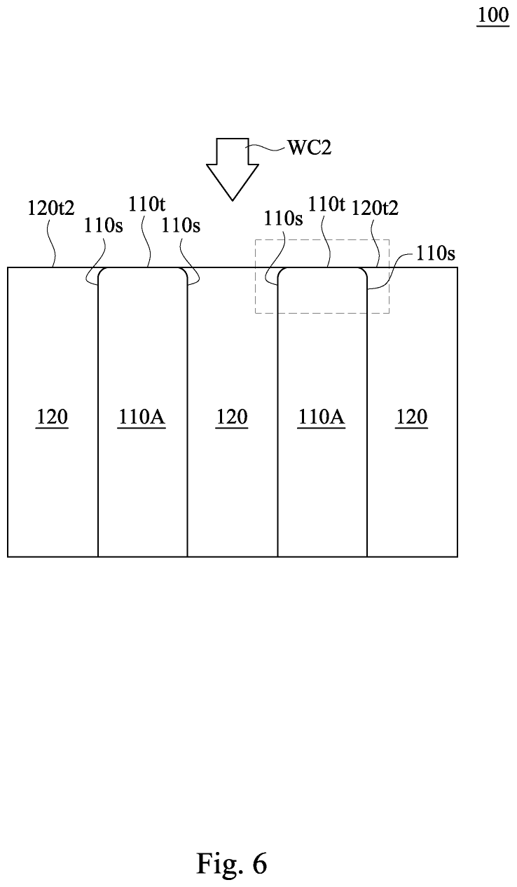

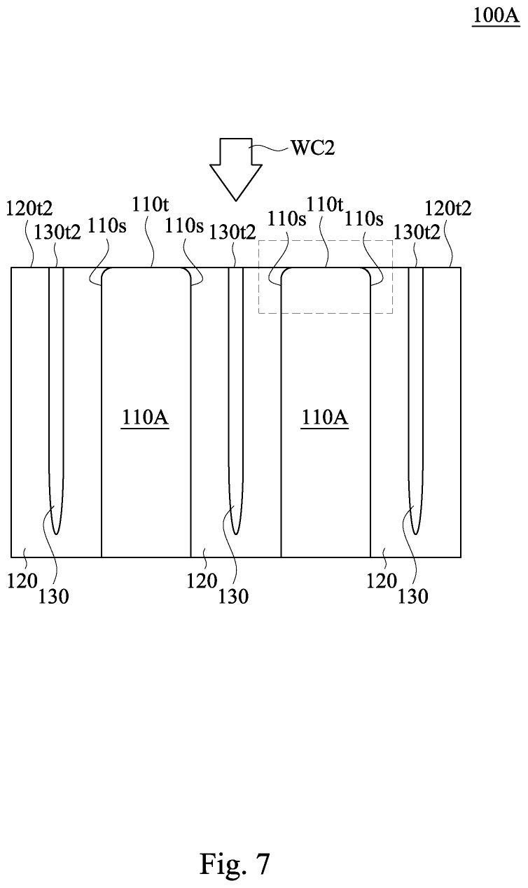

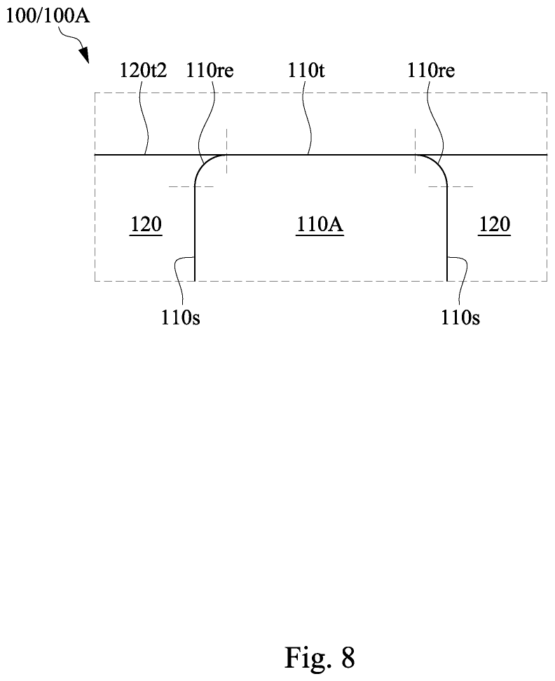

Reference is made to FIG. 1. FIG. 1 is a flow chart of a method M of manufacturing a semiconductor device 100 as shown in FIG. 6 and a semiconductor device 100A as shown in FIG. 7 in accordance with an embodiment of present disclosure. The method M shown in FIG. 1 includes a step S101, a step S102, and a step S103. Please refer to FIG. 1, FIG. 2, and FIG. 3 for better understanding the step S101, refer to FIG. 1 and FIG. 4 for better understanding the step S102, refer to FIG. 1, FIG. 5, FIG. 6, FIG. 7, and FIG. 8 for better understanding the step S103.

Step S101, step S102, and step S103 are described in detail below.

In step S101, a semiconductor structure SMS1 is provided, as shown in FIG. 2.

Reference is made to FIG. 2. FIG. 2 is a cross-sectional view of an intermediate stage of manufacturing the semiconductor device 100 in accordance with an embodiment of present disclosure. As shown in FIG. 2, a semiconductor structure SMS1 is provided. In this embodiment, the semiconductor structure SMS1 includes a silicon substrate 110 and an oxide material 120 on the silicon substrate 110. In some embodiments, the silicon substrate 110 may be an active region (for example, a source/drain region). In some embodiments, the oxide material 120 is configured as shallow trench isolation (STI). More specifically, the silicon substrate 110 has a plurality of trenches T, and the trenches T define a plurality of island structures 110A, as shown in FIG. 2. For simplicity, FIG. 2 merely shows the island structures 110A of the silicon substrate 110 instead of the entire silicon substrate 110. As shown in FIG. 2, the oxide material 120 fills the trenches T of the silicon substrate 110.

As shown in FIG. 2, in some embodiments, the oxide material 120 is filled in the trenches T and covers the silicon substrate 110. More specifically, each of the island structures 110A has a top surface 110t, and the oxide material 120 has a top surface 120t. The oxide material 120 covers the island structure 110A of the silicon substrate 110, so that the top surface 120t of the oxide material 120 is higher than the top surface 110t of the island structures 110A.

As shown in FIG. 2, in some embodiments, each of the island structures 110A further has a width W_{110A}. In some embodiments, the width W_{110A} is substantially equal to a shortest distance between the two adjacent trenches T. In some embodiments, the width W_{110A} of each of the island structures 110A is in a range between 20 nm and 30 nm.

In some embodiments, the method M further comprises planarizing the semiconductor structure SMS1. The step of planarizing the semiconductor structure SMS1 is performed after providing the semiconductor structure SMS1. More specifically, the oxide material 120 overfills the trenches T of the silicon substrate 110 during performing the step S101 and then planarized, such that the top surface 120t is formed accordingly, as shown in FIG. 2. In some embodiments, planarizing the semiconductor structure SMS1 is performed such that the top surface 120t of the oxide material 120 is paralleled to the top surface 110t of the island structures 110A.

Reference is made to FIG. 3. FIG. 3 is a cross-sectional view of an intermediate stage of manufacturing the semiconductor device 100A as shown in FIG. 7 in accordance with an embodiment of present disclosure. The configuration of the semiconductor device 100A and the configuration of the semiconductor device 100 are generally similar. The difference between the semiconductor device 100A and the semiconductor device 100 is that the semiconductor device 100A further includes a filling material 130 with respect to the semiconductor device 100, as shown in FIG. 6 and FIG. 7. As shown in FIG. 3, in another embodiment, the semiconductor structure SMS2 is provided during performing the step S101. In this embodiment, the semiconductor structure SMS2 further includes the silicon substrate 110, the oxide material 120, and the filling material 130. The filling material 130 is formed on the oxide material 120. More specifically, the filling material 130 is filled in seams or void of the oxide material 120 to improve the quality of shallow trench isolation (STI). As shown in FIG. 3, in some embodiments, forming the filling material 130 on the oxide material 120 is performed such that the trenches T are completely filled by the oxide material 120 and the filling material 130.

In some embodiments, the method M further comprises planarizing the semiconductor structure SMS2. The step of planarizing the semiconductor structure SMS2 is performed after providing the semiconductor structure SMS2. More specifically, the oxide material 120 and the filling material 130 overfill the trenches T of the silicon substrate 110 during performing the step S101 and then planarized, such that the top surface 120t of the oxide material 120 and a top surface 130t of the filling material 130 are formed accordingly, as shown in FIG. 3. In some embodiments, planarizing the semiconductor structure SMS2 is performed such that the top surface 120t of the oxide material 120 and the top surface 130t of the filling material 130 are coplanar, as shown in FIG. 3.

In some embodiments, the trenches T may be formed by any suitable method, for example, wet etching, dry etching, or the like. The present disclosure is not intended to limit the methods of forming the trench T.

In some embodiments, the silicon substrate 110 may be composed of silicon-based material. In some embodiments, the silicon substrate 110 may include a material, such as polysilicon, monocrystalline silicon, amorphous silicon, or the like. However, any suitable material may be utilized.

In some embodiments, the silicon substrate 110 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electrochemical plating), electroless plating, or the like. The present disclosure is not intended to limit the methods of forming the silicon substrate 110.

In some embodiments, the oxide material 120 may be composed of oxide. In some embodiments, the oxide material 120 may include a material, such as silicon oxide (SiO₂), or the like. However, any suitable material may be utilized.

In some embodiments, the oxide material 120 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electrochemical plating), electroless plating, or the like. The present disclosure is not intended to limit the methods of forming the oxide material 120.

In some embodiments, the filling material 130 may be composed of nitride. In some embodiments, the filling material 130 may include a material, such as titanium nitride (TiN), silicon nitride (SiₓN_{y}), or the like. However, any suitable material may be utilized.

In some embodiments, the filling material 130 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electrochemical plating), electroless plating, or the like. The present disclosure is not intended to limit the methods of forming the filling material 130.

In step S102, a pad oxide layer 140 is formed on a top portion of the oxide material 120, as shown in FIG. 4.

Reference is made to FIG. 4. FIG. 4 is a cross-sectional view of an intermediate stage of manufacturing the semiconductor device 100 in accordance with an embodiment of present disclosure. As shown in FIG. 4, the pad oxide layer 140 is located over the silicon substrate. More specifically, the pad oxide layer 140 is formed to cover the island structures 110A. In this embodiment, the pad oxide layer 140 is formed on the top portion of the oxide material 120 in situ. In other words, the oxide material 120 is not consumed during performing the step S102. As shown in FIG. 4, the pad oxide layer 140 is formed by a modification process IP. In some embodiments, the top portion of the oxide material 120 which is located on a side close to the top surface 120t of the oxide material 120 is exposed under the performing of the modification process IP. In some embodiments, the modification process IP is performed, such that an etch resistivity of the pad oxide layer 140 is greater than an etch resistivity of the oxide material 120. In some embodiments, the pad oxide layer 140 is configured as a protective layer of the semiconductor structure SMS1 to prevent the semiconductor structure SMS1 from being consumed.

In another embodiment, the filling material 130 may be included in the oxide material 120 shown in FIG. 4 that can be deduced from FIG. 3.

In some embodiments, the pad oxide layer 140 has a thickness T₁₄₀ after performing the modification process IP. In some embodiments, the thickness T₁₄₀ of the pad oxide layer 140 is from the top surface 120t of the oxide material 120 to the top surface 110t of the island structures 110A. In some embodiments, the thickness T₁₄₀ is in a range between 20 nm and 30 nm. In some embodiments, the thickness T₁₄₀ may be regarded as a scope where the modification process IP is performed. In other words, the modification process IP is preferably performed in a depth from the top surface 120t of the oxide material, in which the depth is preferably in a range between 20 nm and 30 nm. In some embodiments in which the aforementioned depth is less than 20 nm or greater than 30 nm, the pad oxide layer 140 may provide less effective protection for the semiconductor structure SMS1 or the semiconductor structure SMS2.

In some embodiments, the modification process IP may be any suitable method, for example, an ion implantation process, or the like. The present disclosure is not intended to limit the methods of forming the pad oxide layer 140.

In some embodiments, the pad oxide layer 140 may be composed of doped oxide. In some embodiments, the pad oxide layer 140 may include a material, such as doped silicon oxide (SiO₂), or the like. In some embodiments, the pad oxide layer 140 is implanted by using carbon ion as dopant. More specifically, forming the pad oxide layer 140 is performed by implanting carbon ion into the top portion of the oxide material 120. However, any suitable dopant may be utilized.

In step S103, The pad oxide layer 140 is removed.

Reference is made to FIG. 5 and FIG. 6. FIG. 5 and FIG. 6 are cross-sectional views of an intermediate stage of manufacturing the semiconductor device 100 in accordance with an embodiment of the present disclosure. In this embodiment, the pad oxide layer 140 is removed from the top portion of the oxide material 120. In some embodiments, the pad oxide layer 140 is removed by a cleaning process. After the step S103 is performed, the semiconductor device 100 is formed.

In some embodiments, the pad oxide layer 140 is removed by two steps of removal. More specifically, as shown in FIG. 5, a portion of the pad oxide layer 140 is removed by a cleaning process WC1, and then an intermediate pad oxide layer 150 is formed in situ. The cleaning process WC1 is performed, so that the intermediate pad oxide layer 150 has a thickness T₁₅₀ and a top surface 120t1. In some embodiments, the thickness T₁₅₀ of the intermediate pad oxide layer 150 is from the top surface 120t1 of the intermediate pad oxide layer 150 to the top surface 110t of the island structures 110A. In some embodiments, the top surface 120t1 is lower than the top surface 120t shown in FIG. 2, FIG. 3, and FIG. 4. In some embodiments, the thickness T₁₅₀ of the intermediate pad oxide layer 150 is less than the thickness T₁₄₀ of the pad oxide layer 140. Subsequently, as shown in FIG. 6, the intermediate pad oxide layer 150 is removed by a cleaning process WC2. The cleaning process WC2 is performed, so that the remaining oxide material 120 has a top surface 120t2. In some embodiments, the top surface 120t2 is lower than the top surface 120t1 shown in FIG. 5. In some embodiments, the pad oxide layer 140 (or, the intermediate pad oxide layer 150) is removed, such that the top surface 120t2 of the oxide material 120 and the top surface 110t of the island structures 110A are coplanar.

Removing the pad oxide layer 140 by the cleaning process WC1 and the cleaning process WC2 has some advantages. One of the advantages is that two-step removal prevents the risk of removal of oxide material 120 induced by over-etching the pad oxide layer 140.

In some embodiments, the cleaning process WC1 and the cleaning process WC2 are performed by using a wet cleaning process, for example, a wet etch process. The present disclosure is not intended to limit the methods of removing the pad oxide layer 140.

In some embodiments, the cleaning process WC1 and the cleaning process WC2 are performed by using, for example, hydrofluoric acid (HF) or the like. However, any suitable material of removing the pad oxide layer 140 may be utilized.

Reference is made to FIG. 7. FIG. 7 is a cross-sectional view of an intermediate stage of manufacturing the semiconductor device 100A in accordance with another embodiment of present disclosure. As shown in FIG. 7, in another embodiment, the semiconductor device 100A is formed after performing the step S103. In this embodiment, the semiconductor device 100A further includes the filling material 130 with respect to the semiconductor device 100 shown in FIG. 6, which can be deduced from FIGS. 3-6.

Reference is made to FIG. 8. FIG. 8 is an enlarged cross-sectional view of FIG. 6 or FIG. 7 of an intermediate stage of manufacturing the semiconductor device 100 and the semiconductor device 100A in accordance with an embodiment of present disclosure. As shown in FIG. 8, each of the island structures 110A further has a side surface 110s and a rounded edge 110re. The top surface 110t of the island structures 110A refers to the surface coplanar with the top surface 120t2 of the oxide material 120. The side surface 110s of the island structures 110A refers to vertical lines located on two opposite sides of each of the island structures 110A shown in FIG. 8. The rounded edge 110re is connected between the top surface 110t and the side surface 110s. As shown in FIG. 8, the top surface 110t, the rounded edge 110re, and the side surface 110s are divided by dotted lines shown in FIG. 8.

In some embodiments, the rounded edge 110re has a radius of curvature. In some embodiments, the radius of curvature of the rounded edge 110re is equal or less than 2.3 nm. In some embodiments, the island structures 110A may not have the rounded edge 110re as the radius of curvature of the rounded edge 110re approaches to zero in theory. In some embodiments in which the radius of curvature of the rounded edge 110 re is equal or less than 2.3 nm, a contact area between each of the island structures 110A and contacts formed on the island structures 110A in subsequent processes may be increased, thereby reducing the resistivity and improving the electrical performance of the semiconductor device 100 and the semiconductor device 100A.

By performing the method M shown in FIG. 1 of the present disclosure, the semiconductor device 100 and the semiconductor device 100A with better electrical performance may be formed.

Based on the above discussions, it can be seen that the semiconductor device and the method of manufacturing the same of the present disclosure provides island structures without rounding issues. In the semiconductor device and the method of manufacturing the same of the present disclosure, since the pad oxide layer is formed on the top of the semiconductor structure and covering the island structures, the loss of the oxide material can be reduced, thereby prevent rounding of the island structures. In the semiconductor device and the method of manufacturing the same of the present disclosure, since the pad oxide layer is formed on the top portion of the oxide material in situ, additional material is not required, thereby improving the electrical performance of the entire semiconductor device. To sum up, the method of manufacturing the semiconductor device of the present disclosure improves the overall electrical performance of the entire semiconductor device.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor device, comprising:
a silicon substrate having a plurality of trenches, and the trenches defining a plurality of island structures; and
an oxide material filled in the trenches,
wherein each of the island structures has a top surface, a side surface connected to the top surface, and a rounded edge connected between the top surface and the side surface, and a radius of curvature of the rounded edge is equal or less than 2.3 nm.

2. The semiconductor device of claim 1, wherein a top surface of the oxide material and the top surface of the island structures are coplanar.

3. The semiconductor device of claim 1, wherein the oxide material does not overfill the trenches.

4. The semiconductor device of claim 1, wherein each of the island structures has a width in a range between 20 nm and 30 nm.

5. The semiconductor device of claim 1, wherein the oxide material contacts a plurality of the side surfaces and a plurality of the rounded edges of the island structures.

6. The semiconductor device of claim 1, wherein the oxide material covers a plurality of the side surfaces and a plurality of the rounded edges of the island structures.

7. The semiconductor device of claim 1, further comprising a filling material on the oxide material.

8. The semiconductor device of claim 7, wherein the filling material and the oxide material completely fill the trenches.

9. The semiconductor device of claim 7, wherein the filling material does not overfill the trenches.

10. The semiconductor device of claim 7, wherein a top surface of the oxide material and a top surface of the filling material are coplanar.

11. The semiconductor device of claim 7, wherein a plurality of the top surfaces of the island structures, a top surface of the oxide material, and a top surface of the filling material are coplanar.

12. The semiconductor device of claim 7, wherein the filling material is filled in seams or voids of the oxide material.

13. The semiconductor device of claim 12, wherein the seams or the voids of the oxide material are recessed from a top surface of the oxide material.

14. The semiconductor device of claim 1, wherein the oxide material exposes a plurality of the top surfaces of the island structures.

15. The semiconductor device of claim 1, wherein the trenches are recessed from a top surface of the silicon substrate.
